(19) United States
(12) Patent Application Publication
(10) Pub. No.: US 2023/0275110 A1
(43) Pub. Date: Aug. 31, 2023

(54) CMOS Image Sensor and Method for Forming the Same

(71) Applicant: HUA HONG SEMICONDUCTOR (WUXI) LIMITED, Wuxi (CN)

(72) Inventor: Junwen LIU, Wuxi (CN)

(21) Appl. No.: 17/983,677

(22) Filed: Nov. 9, 2022

(30) Foreign Application Priority Data
Feb. 28, 2022 (CN) 202210192661.3

(51) Int. Cl. H01L 27/146

(52) U.S. Cl. CPC H01L 27/1463; H01L 27/14636; H01L 27/14643; H01L 27/14689

(57) ABSTRACT

The present disclosure provides a CMOS image sensor and a method for forming the same. The method includes: forming a substrate, a plurality of photosensitive doped layers on the substrate, an isolation layer on the plurality of photosensitive doped layers, and an active layer on the isolation layer, wherein the substrate comprises a plurality of mutually discrete pixel areas, and each photosensitive doped layer is respectively disposed on each pixel area; forming an electrical device in the active layer and on the active layer; forming an interconnection structure in the isolation layer and the active layer, wherein the plurality of photosensitive doped layers are electrically coupled with the electrical device by the interconnection structure. The method can increase working areas of a photosensitive area and a reading circuit area simultaneously, thereby improving a device performance.

### CROSS REFERENCE TO RELATED APPLICATIONS

This application claims the benefit of priority to Chinese patent application No. 202210192661.3, filed on Feb. 28, 2022, the entire disclosures of which are incorporated herein by reference.

### TECHNICAL FIELD

The present disclosure relates to the technical field of semiconductors, and more particularly to a CMOS image sensor and a method for forming the CMOS image sensor.

### BACKGROUND OF THE INVENTION

A CMOS Image Sensor (Complementary-Metal-Oxide-Semiconductor Image Sensor, CIS) is a semiconductor device for converting an optical signal into an electrical signal to realize imaging, which is widely used in devices such as cameras, smart phones, and medical imaging instruments. In recent years, as a pixel density of the CMOS image sensor is becoming higher, the demand for integration and performance of devices is also increased.

A single pixel area of the CMOS image sensor is composed of a photosensitive area and a reading circuit area. A PN junction in the photosensitive area is used to receive an optical signal, and a transistor device in the reading circuit area is used as a switch. The larger the working area of the photosensitive area, the higher the sensitivity of the CMOS image sensor to optical signals. In addition, the larger the working area of the reading circuit area, the more complex reading circuit devices can be accommodated, thereby improving the stability of the devices and reducing device noises. Therefore, for the CMOS image sensor, increasing the working area of the photosensitive area and the reading circuit area can greatly improve overall device performance of the CMOS image sensor.

However, in the prior art, the photosensitive area and the reading circuit area of the CMOS image sensor are arranged in a plane. Therefore, when the pixel density is unchanged, the working areas of the photosensitive area and the reading circuit area need to be balanced within a limited area of each pixel area, which may limits the performance of the device.

### SUMMARY OF THE INVENTION

The present disclosure provides a CMOS image sensor and a method for forming the CMOS image sensor, which can increase working areas of a photosensitive area and a reading circuit area, thereby improving the device performance.

According to an aspect of the present disclosure, a method for forming a CMOS image sensor includes: forming a substrate, a plurality of photosensitive doped layers on the substrate, an isolation layer on the plurality of photosensitive doped layers and an active layer on the isolation layer, wherein the substrate includes a plurality of mutually discrete pixel areas, and each of the plurality of photosensitive doped layers is disposed on each of the plurality of pixel areas respectively; forming an electrical device in the active layer and on the active layer; and forming an interconnection structure in the isolation layer and the active layer, wherein the plurality of photosensitive doped layers are electrically coupled with the electrical device by the interconnection structure.

In some embodiments, forming the substrate, the plurality of photosensitive doped layers, the isolation layer and the active layer includes: forming an initial substrate structure, wherein the initial substrate structure includes the substrate, an initial photosensitive doped layer on the substrate, the isolation layer on the initial photosensitive doped layer, and the active layer on the isolation layer; and forming an isolation structure in the initial substrate structure, wherein the isolation structure penetrates through the initial photosensitive doped layer, and the isolation structure is disposed between adjacent pixel areas, so that the initial photosensitive doped layer forms the plurality of photosensitive doped layers.

In some embodiments, the isolation structure also penetrates through the active layer.

In some embodiments, forming the initial substrate structure includes: providing an initial substrate; injecting a first doping ion into the initial substrate to form the substrate and the initial photosensitive doped layer; forming the isolation layer on the initial photosensitive doped layer; and forming the active layer on the isolation layer.

In some embodiments, forming the initial substrate structure includes: providing an initial substrate, wherein the initial substrate includes a base substrate, the isolation layer on the base substrate, and the active layer on the isolation layer; and injecting a first doping ion into the base substrate to form the substrate and the initial photosensitive doped layer on the substrate.

In some embodiments, forming the initial photosensitive doped layer includes forming the initial photosensitive doped layer by an epitaxial growth process.

In some embodiments, the electrical device includes a gate structure on the substrate and a source drain region respectively disposed in the active layer on two sides of the gate structure.

In some embodiments, the interconnection structure includes a first plug on the active layer, a second plug on one photosensitive doped layer and an electrical coupling layer for coupling the first plug with the second plug, and the first plug is electrically coupled with the electrical device.

In some embodiments, the interconnection structure is made of a material including metal.

In some embodiments, forming the interconnection structure includes: forming an opening in the active layer and the isolation layer, wherein the opening penetrates through the active layer and the isolation layer; forming an interconnection dielectric layer in the opening; forming the first plug on the active layer; forming the second plug penetrating through the interconnection dielectric layer, wherein the second plug is disposed on a surface of the photosensitive doped layer; and forming an electrical coupling layer on a top surface of the first plug and a top surface of the second plug.

In some embodiments, the interconnection structure includes an epitaxial layer disposed in the isolation layer, and the epitaxial layer is in contact with the plurality of photosensitive doped layers and the active layer, and the epitaxial layer is electrically coupled with the electrical device.

In some embodiments, the interconnection structure is made of a material including silicon, silicon germanium and silicon carbide.

In some embodiments, forming the interconnection structure includes: forming an opening in the active layer and the isolation layer, wherein the opening penetrates through the active layer and the isolation layer; and forming the epitaxial layer by an epitaxial growth process in the opening, wherein the epitaxial layer is in contact with a side wall of the active layer.

In some embodiments, the plurality of photosensitive doped layers are doped with N-type ions, and the substrate is doped with P-type ions.

According to another aspect of the present disclosure, a CMOS image sensor includes: a substrate, a plurality of photosensitive doped layers on the substrate, an isolation layer on the plurality of photosensitive doped layers, and an active layer on the isolation layer, wherein the substrate includes a plurality of mutually discrete pixel areas, and each of the plurality of photosensitive doped layers is disposed on each of the plurality of pixel areas respectively; an electrical device disposed in the active layer and on the active layer; and an interconnection structure disposed in the isolation layer and the active layer, wherein the plurality of photosensitive doped layers are electrically coupled with the electrical device by the interconnection structure.

In some embodiments, the method further includes an isolation structure disposed between adjacent photosensitive doped layers and between adjacent pixel areas, wherein the isolation structure penetrates through the plurality of photosensitive doped layers.

In some embodiments, the isolation structure also penetrates through the active layer.

In some embodiments, the electrical device includes a gate structure on the substrate and a source drain region respectively disposed in the active layers on two sides of the gate structure.

In some embodiments, the interconnection structure includes a first plug on the active layer, a second plug on one photosensitive doped layer and an electrical coupling layer for coupling the first plug with the second plug, and the first plug is electrically coupled with the electrical device.

In some embodiments, the interconnection structure includes an epitaxial layer disposed in the isolation layer, and the epitaxial layer is in contact with the plurality of photosensitive doped layers and the active layer, and the epitaxial layer is electrically coupled with the electrical device.

Compared with the prior art, the technical solution of the embodiment of the present disclosure has following beneficial effects:

In the method for forming the CMOS image sensor according to the present disclosure, the electrical device and the photosensitive doped layers are disposed in different layers, thus the space of the substrate, the photosensitive doped layers and the active layer in a direction perpendicular to the surface of the substrate can be fully utilized without being limited to a surface area of the active layer, thus the working areas of the electrical device and the photosensitive doped layers can be increased at the same time, so that the sensitivity of the photosensitive doped layers in the process of receiving optical signals can be improved, and the active layer can also have more space to accommodate electrical devices with higher complexity. Therefore, the stability of the CMOS image sensor can be improved, the noises can be reduced, and the overall performance of the device can be improved.

In the CMOS image sensor according to the present disclose, the electrical device and the photosensitive doped layers are disposed in different layers, thus the space of the substrate, the photosensitive doped layers and the active layer in the direction perpendicular to the surface of the substrate can be fully utilized, thus the working areas of the electrical device and the photosensitive doped layers can be increased at the same time, thereby improving the sensitivity of the photosensitive doped layers in the process of receiving optical signals, improving the stability of the CMOS image sensor, reducing noises and improving the overall performance of the device.

### BRIEF DESCRIPTION OF THE DRAWINGS

FIGS. 1 to 4 are schematic cross-sectional views illustrating a method for forming a CMOS image sensor according to an embodiment of the present disclosure; and

FIG. 5 is a schematic cross-sectional view illustrating a method for forming a CMOS image sensor according to another embodiment of the present disclosure.

### DETAILED DESCRIPTION OF THE EMBODIMENTS

As described in the background, in the prior art, the photosensitive area and the reading circuit area of the CMOS image sensor are arranged in a flat layout. Therefore, under the condition that the pixel density is unchanged, within the limited area of each pixel area, it is necessary to balance the working areas of the photosensitive area and the reading circuit area, which limits the improvement of the performance of the device.

In order to solve above technical problem, the present disclosure provides a method for forming a CMOS image sensor, wherein the electrical device and the photosensitive doped layers are disposed indifferent layers, thus the space of the substrate, the photosensitive doped layers and the active layer in a direction perpendicular to the surface of the substrate can be fully utilized without being limited to a surface area of the active layer, thus the working areas of the electrical device and the photosensitive doped layers can be increased at the same time, so that the sensitivity of the photosensitive doped layers in the process of receiving optical signals can be improved, and the active layer can also have more space to accommodate electrical devices with higher complexity. Therefore, the stability of the CMOS image sensor can be improved, the noises can be reduced, and the overall performance of the device can be improved.

In order to make above purposes, features and beneficial effects of the present disclosure more obvious and understandable, specific embodiments of the present disclosure are described in detail below in combination with accompanying drawings.

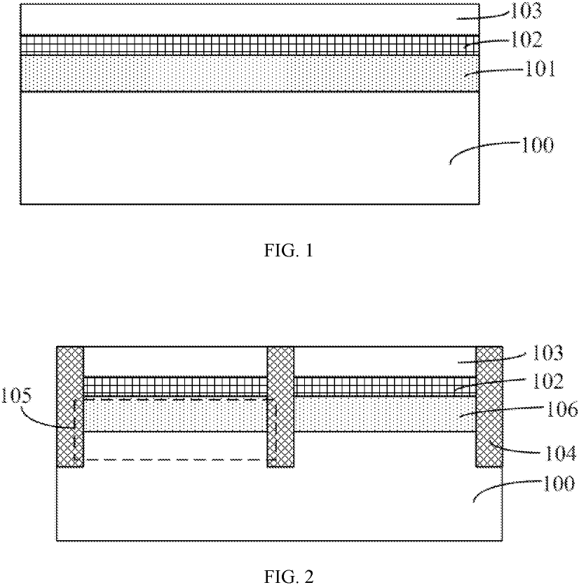

FIGS. 1 to 4 are schematic cross-sectional views illustrating a method for forming a CMOS image sensor according to an embodiment of the present disclosure.

First, a substrate, a plurality of photosensitive doped layers on the substrate, an isolation layer on the plurality of photosensitive doped layers and an active layer on the isolation layer are formed. The substrate includes a plurality of mutually discrete pixel areas, and each of the plurality of photosensitive doped layers is disposed on each of the plurality of pixel areas respectively.

FIGS. 1 to 2 show specific process of forming the substrate, the plurality of photosensitive doped layers, the isolation layer and the active layer.

Referring to FIG. 1, an initial substrate structure (not shown) is formed. The initial substrate structure includes a substrate 100, an initial photosensitive doped layer 101 on the substrate 100, an isolation layer 102 on the initial photosensitive doped layer 101 and an active layer 103 on the isolation layer 102.

The substrate 100 includes a plurality of pixel areas (not shown), and each of the plurality of pixel areas provides a platform for the formation of each photosensitive doped layer and each electrical device.

In some embodiments, the substrate 100 is doped with P-type ions, and the initial photosensitive doped layer 101 is doped with N-type ions. A PN junction is formed between the substrate 100 and the initial photosensitive doped layer 101 for forming a photodiode.

The active layer 103 provides a space for subsequent formation of electrical devices, which are subsequently formed in the active layer 103 and on the active layer 103.

The isolation layer 102 can isolate the initial photosensitive doped layer 101 from the active layer 103, so as to isolate the region of the photodiode from the region where the electrical devices are subsequently formed.

In some embodiments, forming the initial substrate structure includes: providing an initial substrate 100, injecting a first doping ion into the initial substrate 100 to form the substrate 100 and the initial photosensitive doped layer 101, forming the isolation layer 102 on the initial photosensitive doped layer 101, and forming the active layer 103 on the isolation layer 102.

The first doping ion may be N-type ion.

The active layer 103 may be doped with P-type ions.

The material of the isolation layer 102 may be silicon oxide.

In some embodiments, the substrate is doped with P-type ions, and the initial photosensitive doped layer is doped with N-type ions. The initial photosensitive doped layer is formed on the substrate, and the initial photosensitive doped layer may be formed on the substrate by an epitaxial growth process.

In some embodiments, forming the initial substrate structure includes: providing an initial substrate including a base substrate, an isolation layer on the base substrate, and an active layer on the isolation layer; and injecting a first doping ion into the base substrate to form the substrate and the initial photosensitive doped layer on the substrate.

Referring to FIG. 2, an isolation structure 104 is formed in the initial substrate structure. The isolation structure 104 penetrates through the initial photosensitive doped layer 101, and the isolation structure 104 is also disposed between adjacent pixel areas, so that the initial photosensitive doped layer 101 forms a plurality of photosensitive doped layers 106.

The isolation structure 104 penetrates through the initial photosensitive doped layer 101, so that a bottom surface of the isolation structure 104 is lower than an interface between the substrate 100 and the initial photosensitive doped layer 101. Therefore, the isolation structure 104 separates the initial photosensitive doped layer 101 into the plurality of photosensitive doped layers 106. At the same time, the isolation structure 104 is also disposed between adjacent pixel areas, so that a part of the substrate 100 in contact with the initial photosensitive doped layer 101 is separated into several discrete parts by the isolation structure 104, and each photosensitive doped layer 106 is disposed on each pixel area.

The plurality of photosensitive doped layer 106 and a portion of the substrate 100 in contact with the plurality of photosensitive doped layers 106 constitute a plurality of discrete photodiodes, which are used as photosensitive areas 105 of each pixel area to receive optical signals. The isolation structure 104 makes each photosensitive area 105 work independently.

In some embodiments, the isolation structure 104 also penetrates through the active layer 103, so that the subsequently formed electrical devices are independent from each other.

In some embodiments, the isolation structure may not penetrate through the active layer, so that the subsequent electrical devices share a source drain region in the active layer.

Next, an electrical device is formed in active layer 103 and on the active layer 103.

The electrical device includes a gate structure on the substrate 100 and a source drain region 113 in the active layer on two sides of the gate structure.

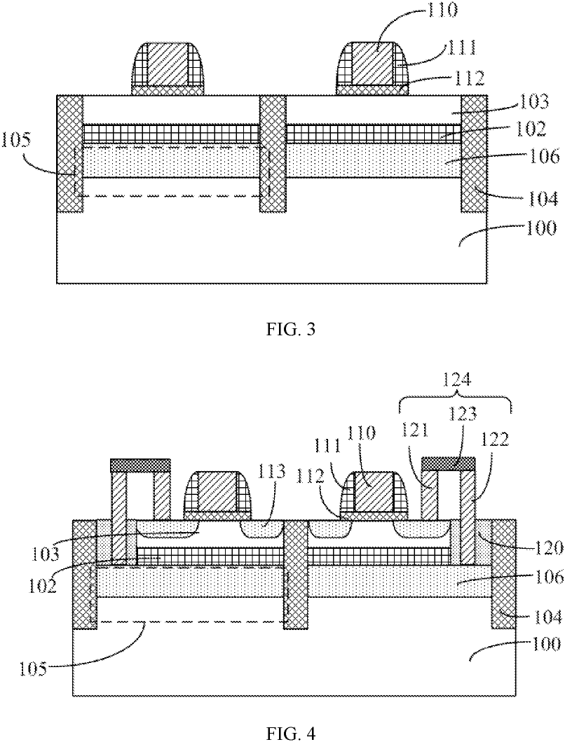

FIG. 3 shows a formation process of the gate structure, and FIG. 4 shows a formation process of the source drain region

Referring to FIG. 3, the gate structure is formed on the active layer 103.

The gate structure includes a gate dielectric layer 112 on the active layer 103, a gate 110 on the gate dielectric layer 112, and side walls 111 on two sides of the gate 110.

In some embodiments, the method for forming the gate structure includes: forming the gate dielectric layer 112 on the active layer 103; forming a pseudo gate (not shown) on the gate dielectric layer 112; forming the side walls 111 on side walls of the pseudo gate; forming an interlayer dielectric layer (not shown) surrounding the pseudo gate and the side walls 111; removing the pseudo gate to form a gate opening; and forming the gate 110 in the gate opening.

Next, the source drain region in the active layer 103 and an interconnection structure in the isolation layer 102 and the active layer 103 are formed. FIG. 4 shows the formation process of the source drain region and the interconnection structure according to an embodiment of the present disclosure.

Referring to FIG. 4, the method for forming the source drain region 113 includes: injecting a second doping ion into the active layer 103 on two sides of the gate 110 to form the source drain region 113.

The source drain region 113 and the gate structure constitute the electrical device, which is used as a switch of the CMOS image sensor to control the conduction of the current.

The second doping ion may be N-type ion.

Still referring to FIG. 4, an interconnection structure 124 is formed in the isolation layer 102 and the active layer 103. The interconnection structure 124 makes the photosensitive dopes layers 106 electrically coupled with the electrical device.

In the CMOS image sensor, each of the electrical devices and each of the photosensitive areas 105 constitute a pixel unit, and each pixel unit operates independently to convert an optical signal into an electrical signal to achieve imaging.

In some embodiments, the photosensitive doped layers 106 and the electrical devices are disposed in different layers, the spaces of the substrate 100, the photosensitive doped layers 106 and the active layers 103 in the direction perpendicular to the surface of the substrate 100 can be fully utilized, without being limited to the surface area of the active layer 103. Therefore, on the basis of keeping the surface area of each pixel unit unchanged, the working areas of the electrical devices and the photosensitive area 105 are increased at the same time, thereby improving the sensitivity of the photosensitive area 105 in the process of receiving optical signals, and also enabling the active layer 103 to have more space to accommodate more complex electrical devices, thereby improving the stability of the CMOS image sensor, reducing noises, and improving the overall performance of the device.

In some embodiment, the interconnection structure 124 includes a first plug 121 on the active layer 103, a second plug 122 on one photosensitive doped layer 106, and an electrical coupling layer 123 for coupling the first plug 121 with the second plug 122. The first plug 121 is electrically coupled with the electrical device.

Specifically, the first plug 121 is coupled with the source drain region 113, and the second plug 122 is coupled with the photosensitive doped layer 106, so that the interconnection structure 124 electrically coupled the electrical device with the photosensitive area 105.

In some embodiments, the material of the interconnection structure 124 includes metal, so that the interconnection structure 124 has lower resistance, thereby obtaining a better electrical connection effect between the photosensitive doped layer 106 and the electrical device.

In some embodiments, the method for forming the interconnection structure 124 includes: forming an opening (not shown) in the active layer 103 and the isolation layer 102, wherein the opening penetrates through the active layer 103 and the isolation layer 102; forming an interconnection dielectric layer 120 in the opening; forming the first plug 121 on the active layer 103; forming the second plug 122 penetrating through the interconnection dielectric layer 120 on the surface of the photosensitive doped layer 106; and forming the electrical coupling layer 123 on a top surface of the first plug 121 and a top surface of the second plug 122.

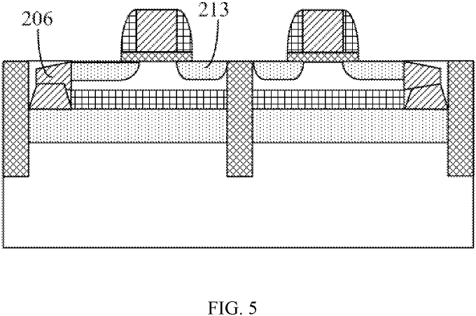

FIG. 5 is a schematic cross-sectional view illustrating a method for forming a CMOS image sensor according to another embodiment of the present disclosure.

Referring to FIG. 5 on the basis of FIG. 3, the interconnection structure is formed in the isolation layer and the active layer, and the interconnection structure makes the photosensitive doped layer and the electrical device electrically coupled with each other.

The interconnection structure includes an epitaxial layer 206 in the isolation layer. The epitaxial layer 206 is in contact with the photosensitive doped layer and the active layer, and the epitaxial layer 206 is electrically coupled with the electrical device.

The material of the interconnection structure may include silicon, silicon germanium and silicon carbide.

The method for forming the interconnection structure includes: forming an opening in the active layer and the isolation layer, wherein the opening penetrates through the active layer and the isolation layer; and forming the epitaxial layer 206 by an epitaxial growth process in the opening. The epitaxial layer 206 is in contact with the side wall of the active layer.

Specifically, in the process of forming the epitaxial layer 206, the epitaxial layer 206 may be formed a surface of the side wall of the active layer and the surface of the photosensitive doped layer at the same time until they are in contact with each other, so that the active layer and the photosensitive doped layer are coupled with each other. Therefore, the forming process of the interconnection structure is simple.

After the interconnection structure is formed, a second doping ion is injected into the epitaxial layer 206 on two sides of the gate, so as to form a source drain region 213 on two sides of the gate. The source drain region 213 is in contact with one end of the epitaxial layer 206, and the other end of the epitaxial layer 206 is in contact with the photosensitive doped layer, so that the electrical device is electrically coupled with the photosensitive area.

Since injecting the second doping ion on two sides of the gate and in the epitaxial layer can be carried out simultaneously, the steps of the preparation process are simplified.

Correspondingly, the embodiment of the present disclosure also provides a CMOS image sensor formed by the above method.

Still referring to FIG. 4, the CMOS image sensor includes a substrate 100, a plurality of photosensitive doped layers 106 on the substrate 100, an isolation layer 102 on the plurality of photosensitive doped layers 106, and an active layer 103 on the isolation layer 102; electrical devices disposed in the active layer 103 and on the active layer 103; an interconnection structure 124 disposed in the isolation layer 102 and the active layer 103. The substrate 100 includes a plurality of mutually discrete pixel areas, and each of the plurality of photosensitive doped layers 106 is disposed on each of the plurality of pixel areas respectively. The interconnection structure 124 electrically connects the photosensitive doped layers 106 with the electrical device.

In some embodiments, the CMOS image sensor also includes an isolation structure 104 disposed between adjacent photosensitive doped layers 106 and adjacent pixel areas, and the isolation structure 104 penetrates through the photosensitive doped layers 106.

In some embodiments, the isolation structure 104 also penetrates through the active layer 103.

In some embodiments, the electrical device includes a gate structure disposed on the substrate 100 and a source drain region 113 disposed in the active layers 103 on two sides of the gate structure.

In some embodiments, the interconnection structure 124 includes a first plug 121 disposed on the active layer 103, a second plug 122 disposed on the photosensitive doped layers 106, and an electrical coupling layer 123 for coupling the first plug 121 with the second plug 122. The first plug 121 is electrically coupled with the electrical device.

FIG. 5 shows a CMOS image sensor according to another embodiment of the present disclosure. The difference between the CMOS image sensor in FIG. 5 and the CMOS image sensor in FIG. 4 is that the interconnection structure of the CMOS image sensor in FIG. 5 includes an epitaxial layer 206 in the isolation layer. The epitaxial layer 206 is in contact with the photosensitive doped layers and the active layer, and the epitaxial layer 206 is electrically coupled with the electrical device.

Although the present disclosure has been disclosed above, the present disclosure is not limited thereto. Any changes and modifications may be made by those skilled in the art without departing from the spirit and scope of the present disclosure, and the scope of the present disclosure should be determined by the appended claims.

What i claim is:

1. A method for forming a CMOS image sensor, comprising:
forming a substrate, a plurality of photosensitive doped layers on the substrate, an isolation layer on the plurality of photosensitive doped layers and an active layer on the isolation layer, wherein the substrate comprises a plurality of mutually discrete pixel areas, and each of the plurality of photosensitive doped layers is disposed on each of the plurality of pixel areas respectively;
forming an electrical device in the active layer and on the active layer; and
forming an interconnection structure in the isolation layer and the active layer, wherein the plurality of photosensitive doped layers are electrically coupled with the electrical device by the interconnection structure.

2. The method according to claim 1, wherein forming the substrate, the plurality of photosensitive doped layers, the isolation layer and the active layer comprises:
forming an initial substrate structure, wherein the initial substrate structure comprises the substrate, an initial photosensitive doped layer on the substrate, the isolation layer on the initial photosensitive doped layer and the active layer on the isolation layer; and
forming an isolation structure in the initial substrate structure, wherein the isolation structure penetrates through the initial photosensitive doped layer, and the isolation structure is disposed between adjacent pixel areas, so that the initial photosensitive doped layer forms the plurality of photosensitive doped layers.

3. The method according to claim 2, wherein the isolation structure also penetrates through the active layer.

4. The method according to claim 2, wherein forming the initial substrate structure comprises:
providing an initial substrate;
injecting a first doping ion into the initial substrate to form the substrate and the initial photosensitive doped layer;
forming the isolation layer on the initial photosensitive doped layer; and
forming the active layer on the isolation layer.

5. The method according to claim 2, wherein forming the initial substrate structure comprises:
providing an initial substrate, wherein the initial substrate comprises a base substrate, the isolation layer on the base substrate, and the active layer on the isolation layer; and
injecting a first doping ion into the base substrate to form the substrate and the initial photosensitive doped layer on the substrate.

6. The method according to claim 2, wherein forming the initial photosensitive doped layer comprises forming the initial photosensitive doped layer by an epitaxial growth process.

7. The method according to claim 1, wherein the electrical device comprises a gate structure on the substrate and a source drain region respectively disposed in the active layer on two sides of the gate structure.

8. The method according to claim 1, wherein the interconnection structure comprises a first plug on the active layer, a second plug on one photosensitive doped layer and an electrical coupling layer for coupling the first plug with the second plug, and the first plug is electrically coupled with the electrical device.

9. The method according to claim 8, wherein the interconnection structure is made of a material comprising metal.

10. The method according to claim 8, wherein forming the interconnection structure comprises:
forming an opening in the active layer and the isolation layer, wherein the opening penetrates through the active layer and the isolation layer;
forming an interconnection dielectric layer in the opening;
forming the first plug on the active layer;
forming the second plug penetrating through the interconnection dielectric layer, wherein the second plug is disposed on a surface of the photosensitive doped layer; and
forming an electrical coupling layer on a top surface of the first plug and a top surface of the second plug.

11. The method according to claim 1, wherein the interconnection structure comprises an epitaxial layer disposed in the isolation layer, and the epitaxial layer is in contact with the plurality of photosensitive doped layers and the active layer, and the epitaxial layer is electrically coupled with the electrical device.

12. The method according to claim 11, wherein the interconnection structure is made of a material comprising silicon, silicon germanium and silicon carbide.

13. The method according to claim 12, wherein forming the interconnection structure comprises:
forming an opening in the active layer and the isolation layer, wherein the opening penetrates through the active layer and the isolation layer; and
forming the epitaxial layer by an epitaxial growth process in the opening, wherein the epitaxial layer is in contact with a side wall of the active layer.

14. The method according to claim 1, wherein the plurality of photosensitive doped layers are doped with N-type ions, and the substrate is doped with P-type ions.

15. A CMOS image sensor, comprising:
a substrate, a plurality of photosensitive doped layers on the substrate, an isolation layer on the plurality of photosensitive doped layers, and an active layer on the isolation layer, wherein the substrate comprises a plurality of mutually discrete pixel areas, and each of the plurality of photosensitive doped layers is disposed on each of the plurality of pixel areas respectively;
an electrical device disposed in the active layer and on the active layer; and
an interconnection structure disposed in the isolation layer and the active layer, wherein the plurality of photosensitive doped layers are electrically coupled with the electrical device by the interconnection structure.

16. The CMOS image sensor according to claim 15, further comprising an isolation structure disposed between adjacent photosensitive doped layers and between adjacent pixel areas, wherein the isolation structure penetrates through the plurality of photosensitive doped layers.

17. The CMOS image sensor according to claim 16, wherein the isolation structure also penetrates through the active layer.

18. The CMOS image sensor according to claim 15, wherein the electrical device comprises a gate structure on the substrate and a source drain region respectively disposed in the active layers on two sides of the gate structure.

19. The CMOS image sensor according to claim 15, wherein the interconnection structure comprises a first plug on the active layer, a second plug on one photosensitive doped layer and an electrical coupling layer for coupling the first plug with the second plug, and the first plug is electrically coupled with the electrical device.

20. The CMOS image sensor according to claim 15, wherein the interconnection structure comprises an epitaxial layer disposed in the isolation layer, and the epitaxial layer is in contact with the plurality of photosensitive doped layers and the active layer, and the epitaxial layer is electrically coupled with the electrical device.
